(19) United States
(12) Patent Application Publication
(10) Pub. No.: US 2026/0013355 A1
(43) Pub. Date: Jan. 8, 2026

(54) DISPLAY PANEL AND DISPLAY APPARATUS

(71) Applicants: BOE TECHNOLOGY GROUP CO., LTD., Beijing (CN); CHENGDU BOE OPTOELECTRONICS TECHNOLOGY CO., LTD., Sichuan (CN)

(72) Inventors: Shilong WANG, Beijing (CN); Mengqi WANG, Beijing (CN); Ge NIU, Beijing (CN); Ziyang YU, Beijing (CN); Zhiliang JIANG, Beijing (CN); Ming HU, Beijing (CN); Fei CHEN, Beijing (CN)

(21) Appl. No.: 18/992,221

(22) PCT Filed: Jul. 21, 2023
(86) PCT No.: PCT/CN2023/108584

§ 371 Date: Jan. 8, 2025

(30) Foreign Application Priority Data
Jul. 29, 2022 (CN) 202210907575.6

(51) Int. Cl. H10K 59/131; H10K 59/126

(52) U.S. Cl. CPC H10K 59/1315; H10K 59/126

(57) ABSTRACT

A display panel includes: a base substrate, a lead-out line, a detection unit and a first power source access line, wherein the base substrate includes a first fan-out area, a bent area, an integrated area and a second fan-out area, which are located in a first frame area; the orthographic projection of the lead-out line on the base substrate is located in the bent area, and the lead-out line is connected to a first fan-out line which is located in the first fan-out area; the orthographic projection of the detection unit on the base substrate is located in the integrated area, and the detection unit is connected to the lead-out line; the first power source access line includes a first extension portion, a second extension portion and a third extension portion, the first extension portion being connected between the second extension portion and the third extension portion.

### CROSS-REFERENCE TO RELATED APPLICATIONS

The present disclosure is a U.S. National Stage of International Application No. PCT/CN2023/108584, filed on Jul. 21, 2023, which is based on and claims the priority to the Chinese Patent Application NO. 202210907575.6, entitled “DISPLAY PANEL AND DISPLAY DEVICE”, filed on Jul. 29, 2022, the entire contents of both of which are hereby incorporated by reference as a part of the present disclosure.

### TECHNICAL FIELD

The present disclosure relates to the field of display technologies, and in particular to a display panel and a display device.

### BACKGROUND

In the related arts, a border area of a display panel is provided with a power access line, which is configured to provide a power signal to the display panel. In the related arts, the power access line is coupled to a power line in a display area through multiple access ports.

It should be noted that the information disclosed in the Background section above is only for enhancing the understanding of the background of the present disclosure, and thus may include information that does not constitute prior art known to those of ordinary skill in the art.

### SUMMARY

According to an aspect of the present disclosure, there is provided a display panel, including: a base substrate, a plurality of sub-pixels, a plurality of data lines, a plurality of first fan-out lines, a plurality of lead-out lines, a detection unit, and a first power access line. The base substrate includes a display area and a first border area coupled to a side of the display area in a second direction, the first border area includes a first fan-out area, a bending area, an integrated area, and a second fan-out area, the bending area is coupled to a side of the first fan-out area away from the display area, the integrated area is coupled to a side of the bending area away from the first fan-out area, and the second fan-out area is coupled to a side of the integrated area away from the bending area; orthographic projections of the plurality of sub-pixels on the base substrate are located in the display area; orthographic projections of the plurality of data lines on the base substrate are located in the display area, and the data lines are configured to provide data signals to the sub-pixels; orthographic projections of the plurality of first fan-out lines on the base substrate are located in the first fan-out area, the first fan-out lines are arranged corresponding to the data lines, and the first fan-out lines are coupled to corresponding data lines; orthographic projections of the plurality of lead-out lines on the base substrate are located in the bending area, the lead-out lines are arranged corresponding to the first fan-out lines, and the lead-out lines are coupled to corresponding first fan-out lines; an orthographic projection of the detection unit on the base substrate is located in the integrated area, and the detection unit is coupled to the lead-out lines; the first power access line is configured to provide a first power signal to the sub-pixel, and the first power access line includes a first extension portion, a second extension portion, and a third extension portion, and the first extension portion is coupled between the second extension portion and the third extension portion; wherein an orthographic projection of the first extension portion on the base substrate is extended along a first direction and is located in the second fan-out area, an orthographic projection of the second extension portion on the base substrate is extended along the second direction and is at least partially located in the bending area, an orthographic projection of the third extension portion on the base substrate is extended along the second direction and is at least partially located in the bending area, and the first direction is intersected with the second direction; and in the first direction, the orthographic projections of the lead-out lines on the base substrate are located between the orthographic projection of the second extension portion on the base substrate and the orthographic projection of the third extension portion on the base substrate.

According to an aspect of the present disclosure, there is provided a display device, including the above-mentioned display panel.

It should be noted that the above general description and the following detailed description are merely exemplary and explanatory and should not be construed as limiting of the disclosure.

### BRIEF DESCRIPTION OF THE DRAWINGS

The drawings herein are incorporated in and constitute a part of the specification, illustrate embodiments consistent with the present disclosure, and together with the description serve to explain principles of the present disclosure. Apparently, the drawings in the following description are only some embodiments of the present disclosure. For those of ordinary skill in the art, other drawings may be obtained based on these drawings without paying any creative effort.

FIG. 1 is a schematic structural diagram of an example embodiment of a display panel in the present disclosure;

FIG. 2 is a schematic structural diagram of a pixel driving circuit in an example embodiment of a display panel in the present disclosure;

FIG. 3 is a partial enlarged view of a first border area in an example embodiment of a display panel in the present disclosure;

FIG. 4 is a schematic structural diagram of a first border area in another example embodiment of a display panel in the present disclosure;

FIG. 5 is a schematic structural diagram of individual signal lines in FIG. 4;

FIG. 6 is a schematic structural diagram of a first power access line and a second power access line in FIG. 4;

FIG. 7 is a partial enlarged view of a first fan-out area in FIG. 4;

FIG. 8 is a schematic structural diagram of a bending area in FIG. 4;

FIG. 9 is a partial enlarged view of a second fan-out area and a binding area in FIG. 4;

FIG. 10 is a structural layout diagram of a first gate layer in FIG. 9;

FIG. 11 is a structural layout diagram of a second gate layer in FIG. 9;

FIG. 12 is a structural layout diagram of a first source-drain layer in FIG. 9;

FIG. 13 is a structural layout diagram of a second source-drain layer in FIG. 9;

FIG. 14 is a structural layout diagram of a third source-drain layer in FIG. 9;

FIG. 15 is a cross-sectional view taken along a dotted line CC in FIG. 9;

FIG. 16 is a structural layout diagram of a first power access line and a second power access line in FIG. 6;

FIG. 17 is a structural layout diagram of a first source-drain layer in FIG. 16;

FIG. 18 is a structural layout diagram of a second source-drain layer in FIG. 16;

FIG. 19 is a structural layout diagram of a third source-drain layer in FIG. 16; and

FIG. 20 is a diagram showing a resistance variation of data lead-out lines at different positions of a display panel in the present disclosure.

### DETAILED DESCRIPTION

Example embodiments will now be described more fully with reference to the accompanying drawings. However, the example embodiments can be implemented in a variety of forms and should not be construed as being limited to examples set forth herein; rather, these embodiments are provided so that the present disclosure will be more complete and comprehensive so as to convey the idea of the example embodiments to those skilled in this art. The same reference numerals in the drawings denote the same or similar structures, and the repeated description thereof will be omitted.

The terms “one”, “a”, and “the” are used to indicate that there are one or more elements/components or the like; the terms “include” and “have” are used to indicate an open meaning of including and means that there may be additional elements/components/etc. in addition to the listed elements/components/etc.

As described above, in the related arts, a border area of a display panel is provided with a power access line, which is configured to provide a power signal to the display panel. In the related arts, the power access line is coupled to a power line in a display area through multiple access ports. However, a data fan-out line in the border area needs to avoid the access port of the power access line, which leads to a sudden change in the length of adjacent data lines in the display panel, and ultimately causes the display panel split screen mura phenomenon.

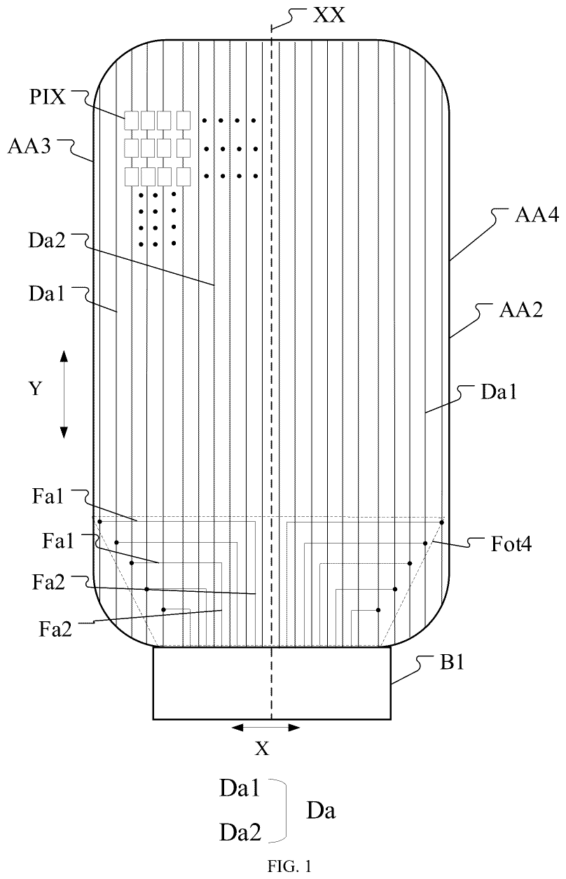

FIG. 1 is a schematic structural diagram of an example embodiment of a display panel in the present disclosure. As shown in FIG. 1, the display panel includes a base substrate, a sub-pixel PIX, a plurality of data lines Da, a first data connection line Fa1, and a second data connection line Fa2. The base substrate may include a display area AA, and a fourth fan-out area Fot4 located in the display area AA.

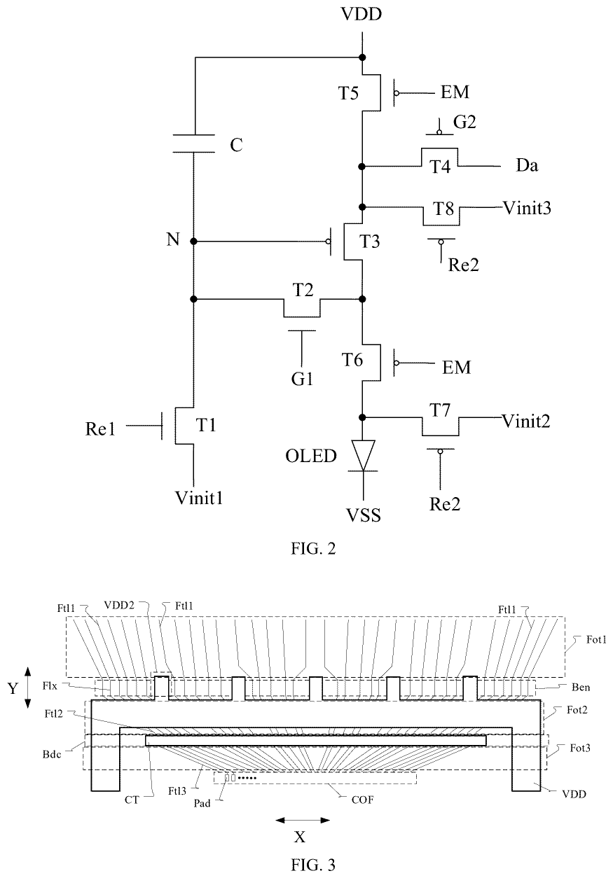

An orthographic projection of the sub-pixel PIX on the base substrate is located in the display area AA, and the sub-pixel PIX may include a pixel driving circuit and a light-emitting unit, and the pixel driving circuit is configured to drive the light-emitting unit to emit light. FIG. 2 is a schematic structural diagram of a pixel driving circuit in an example embodiment of a display panel in the present disclosure. As shown in FIG. 2, the pixel driving circuit may include: a driving transistor T3, a first transistor T1, a second transistor T2, a fourth transistor T4, a fifth transistor T5, a sixth transistor T6, a seventh transistor T7, an eighth transistor T8, and a capacitor C. A first electrode of the fourth transistor T4 is coupled to a data signal terminal Da, a second electrode of the fourth transistor T4 is coupled to a first electrode of the driving transistor T3, and a gate of the fourth transistor T4 is coupled to a second gate driving signal terminal G2. A first electrode of the fifth transistor T5 is coupled to a first power terminal VDD, a second electrode of the fifth transistor T5 is coupled to the first electrode of the driving transistor T3, and a gate of the fifth transistor T5 is coupled to an enable signal terminal EM. A gate of the driving transistor T3 is coupled to a node N. A first electrode of the second transistor T2 is coupled to the node N, a second electrode of the second transistor T2 is coupled to a second electrode of the driving transistor T3, and a gate of the second transistor T2 is coupled to a first gate driving signal terminal G1. A first electrode of the sixth transistor T6 is coupled to the second electrode of the driving transistor T3, a second electrode of the sixth transistor T6 is coupled to a second electrode of the seventh transistor T7, and a gate of the sixth transistor T6 is coupled to the enable signal terminal EM. A first electrode of the seventh transistor T7 is coupled to a second initial signal terminal Vinit2, and a gate of the seventh transistor T7 is coupled to a second reset signal terminal Re2. A second electrode of the first transistor T1 is coupled to the node N, a first electrode of the first transistor T1 is coupled to a first initial signal terminal Vinit1, and a gate of the first transistor T1 is coupled to a first reset signal terminal Re1. A first electrode of the capacitor C is coupled to the node N, and a second electrode of the capacitor C is coupled to the first power terminal VDD. A first electrode of the eighth transistor T8 is coupled to a third initial signal line Vinit3, a second electrode of the eighth transistor T8 is coupled to the first electrode of the driving transistor, and a gate of the eighth transistor T8 is coupled to a second reset signal terminal Re2. The pixel driving circuit may be coupled to a light-emitting unit OLED to drive the light-emitting unit OLED to emit light, and the light-emitting unit OLED may be coupled between the second electrode of the sixth transistor T6 and a second power terminal VSS. The first transistor T1 and the second transistor T2 may be N-type transistors; the driving transistor T3, the fourth transistor T4, the fifth transistor T5, the sixth transistor T6, the seventh transistor T7, and the eighth transistor T8 may be P-type transistors.

A driving method of the pixel driving circuit may include a reset phase, a data writing phase, and a light emitting phase. In the reset phase, the first reset signal terminal Re1 outputs a high level signal, the second reset signal terminal Re2 outputs a low level signal, the first transistor T1 and the eighth transistor T8 are turned on, the first initial signal terminal Vinit1 inputs a first initial signal to the node N, and the third initial signal terminal Vinit3 inputs a third initial signal to the first electrode of the driving transistor T3. In the data writing phase, the first gate driving signal terminal G1 outputs a high level signal, the second gate driving signal terminal G2 outputs a low level signal, the second transistor T2 and the fourth transistor T4 are turned on, and the data signal terminal Da also outputs a data signal to write a compensation voltage Vdata+Vth to the node N, where Vdata is a voltage of the data signal, and Vth is a threshold voltage of the driving transistor T3. In the ight emitting phase, the enable signal terminal EM outputs a low level signal, the sixth transistor T6 and the fifth transistor T5 are turned on, and the driving transistor T3 drives the light emitting unit to emit light under the action of the compensation voltage Vdata+Vth stored in the capacitor C. The output current of the driving transistor in the pixel driving circuit of the present disclosure is I=(μWCox/2L) (Vdata+Vth−Vdd−Vth)². The pixel driving circuit can avoid the influence of the threshold of the driving transistor on its output current. I is the output current of the driving transistor; μ is the carrier mobility; Cox is a gate capacitance per unit area, W is a width of a channel of the driving transistor, L is a length of the channel of the driving transistor, Vgs is a gate-source voltage difference of the driving transistor, and Vth is the threshold voltage of the driving transistor.

In an example embodiment, as shown in FIG. 1, an orthogonal projection of the data line Da on the base substrate is located in the display area AA, and the data line Da is configured to provide a data signal to the sub-pixel PIX coupled thereto, and the pixel driving circuit in the sub-pixel PIX can provide a driving current to the light-emitting unit under the control of the data signal, thereby controlling the gray scale of the sub-pixel. The orthogonal projections of the data lines Da on the base substrate can be distributed at intervals along a first direction X and extend along a second direction Y, and the first direction X and the second direction Y can intersect, for example, the first direction X can be a row direction, and the second direction Y can be a column direction. The plurality of data lines Da may include a first data line Da1 and a second data line Da2. The display area AA includes a third side edge AA3 and a fourth side edge AA4 that are arranged opposite to each other in the first direction X. An orthogonal projection of the first data line Da1 on the base substrate is located on a side of an orthogonal projection of the second data line Da2 on the base substrate that is close to the third side edge AA3 or the fourth side edge AA4. Orthographic projections of first data connection lines Fa1 on the base substrate are distributed at intervals along the second direction Y and extend along the first direction X. The first data connection lines Fa1 are coupled to the first data lines Da1, and orthographic projections of at least part of the first data connection lines Fa1 on the base substrate overlap with orthographic projections of at least part of the second data lines Da2 on the base substrate. Orthographic projections of the second data connection lines Fa2 on the base substrate are distributed along the first direction X at intervals and extend along the second direction Y. The second data connection lines Fa2 are coupled to the first data connection lines Fal. In an example embodiment, the fourth fan-out area Fot4 is arranged in the display area AA, so that the narrow border design of the display panel can be realized.

In an example embodiment, as shown in FIG. 1, a dividing line XX divides the display area AA into two display areas distributed in the first direction X, and the dividing line XX may be located at a midline position of the display area AA in the first direction X. The first data line Da1 away from a side of the dividing line XX may be coupled to the second data connection line Fa2 close to the side of the dividing line XX through the first data connection line Fa1. It should be understood that in other example embodiments, the first data connection line Fa1 and the second data connection line Fa2 may also be arranged in other ways. For example, the first data line Da1 close to the side of the dividing line XX is coupled to the second data connection line Fa2 close to the side of the dividing line XX through the first data connection line Fal. For another example, lengths of the first data connection lines Fa1 may also gradually increase or decrease from top to bottom.

As shown in FIG. 1, the base substrate may further include a first border area B1. The first border area B1 is coupled to a side of the display area AA in the second direction Y. FIG. 3 is a partial enlarged view of a first border area B1 in an example embodiment of a display panel in the present disclosure. As shown in FIG. 3, the first border area B1 may include a first fan-out area Fot1, a bending area Ben, a second fan-out area Fot2, an integrated area Bdc, a third fan-out area Fot3, and a binding area COF. The bending area Ben is coupled to a side of the first fan-out area Fot1 away from the display area AA. The second fan-out area Fot2 is coupled to a side of the bending area Ben away from the first fan-out area Fot1. The integrated area Bdc is coupled to a side of the second fan-out area Fot2 away from the bending area Ben. The third fan-out area Fot3 is coupled to a side of the integrated area Bdc away from the second fan-out area Fot2. The binding area COF is located on a side of the third fan-out area Fot3 away from the integrated area Bdc.

As shown in FIG. 3, the display panel may further include: a plurality of first fan-out lines Ftl1, a plurality of lead-out lines Flx, a plurality of second fan-out lines Ftl2, a detection unit CT, a plurality of third fan-out lines Ftl3, a first power access line VDD, and a plurality of binding pins Pad. Orthographic projections of the plurality of first fan-out lines Ftl1 on the base substrate are located in the first fan-out area Fot1, the first fan-out lines Ftl1 are arranged corresponding to the data lines Da, and the first fan-out lines Ftl1 are coupled to the corresponding data lines. The first fan-out lines Ftl1 may be coupled to the first data lines Da1 through the second data connection lines Fa2, or directly coupled to the second data lines Da2. Orthographic projections of the plurality of lead-out lines Flx on the base substrate are located in the bending area Ben, the lead-out lines Flx are arranged corresponding to the first fan-out lines Ftl1, and the lead-out lines Flx are coupled to the corresponding first fan-out lines Ftl1. The second fan-out lines Ftl2 are arranged corresponding to the lead-out lines Flx, and the second fan-out lines Ftl2 are coupled to the corresponding lead-out lines Flx. As shown in FIG. 1, since the orthographic projections of at least part of the first data connection lines Fa1 on the base substrate intersect with the orthographic projections of the second data lines Da2 on the base substrate, this arrangement makes the data lead-out lines formed by the second data connection lines Fa2 and the second data lines Da2 and the data lines Da have different arrangement orders in the first direction X, which leads to incompatibility with conventional integrated circuits. In an example embodiment, it is necessary to change the order of the lead-out lines Flx in the second fan-out area Fot2, so that ends of the second fan-out lines Ftl2 that enter the integrated area Bdc have the same arrangement order as the at a lines Da in the first direction X. A partial structure of the orthographic projection of the first power access line VDD on the base substrate can be located in the second fan-out area Fot2, and the first power access line VDD can be configured to provide a first power signal to the sub-pixel, and the first power signal can be a high-level power signal. For example, the first power access line VDD can be configured to provide the first power terminal in FIG. 2 to the pixel driving circuit. An orthographic projection of the detection unit CT on the base substrate is located in the integrated area Bdc, and the detection unit CT is coupled to the second fan-out line Ftl2. The detection unit CT can be coupled to the data line Da through the second fan-out line Ftl2, and the detection unit CT can perform functional detection on the data line Da and the display panel. For example, the detection unit CT can detect whether the data line is short-circuited or open-circuited. For another example, the detection unit CT can perform pure color display detection on the display panel. Orthographic projections of the third fan-out lines Ftl3 on the base substrate can be located in the third fan-out area Fot, and the third fan-out lines Ftl3 can be arranged corresponding to the second fan-out lines Ftl2, and the third fan-out lines Ftl3 can be coupled to the corresponding second fan-out lines Ftl2. Orthographic projection of the binding pins Pad on the base substrate are located in the binding area COF, and the binding pins Pad are correspondingly coupled to the third fan-out lines Ftl3. The binding pin Pad can be configured to bind the driving circuit, and the driving circuit can be configured to provide a data signal to the data line Da.

As shown in FIG. 3, the first power access line VDD may include a plurality of access terminals VDD2, an orthographic projection of the access terminal VDD2 on the base substrate extends along the second direction Y and is at least partially located in the bending area Ben. In an example embodiment, the part of the access terminal VDD2 whose orthographic projection on the base substrate is located in the bending area Ben may be located in the same conductive layer as the lead-out line Flx. Thus, when the first fan-out line Ftl1 is introduced into the bending area Ben, it is necessary to avoid the access terminal VDD2. As shown in FIG. 3, extension lengths of first fan-out lines Ftl1 on two adjacent sides of the access terminal VDD2 will suddenly change, resulting in a sudden change in the resistance of the data line itself, which will cause the split screen mura phenomenon in severe cases. In addition, in the embodiment shown in FIG. 3, a size of the second fan-out area Fot2 in the second direction is relatively small, which is not conducive to changing the order of the data lead-out lines.

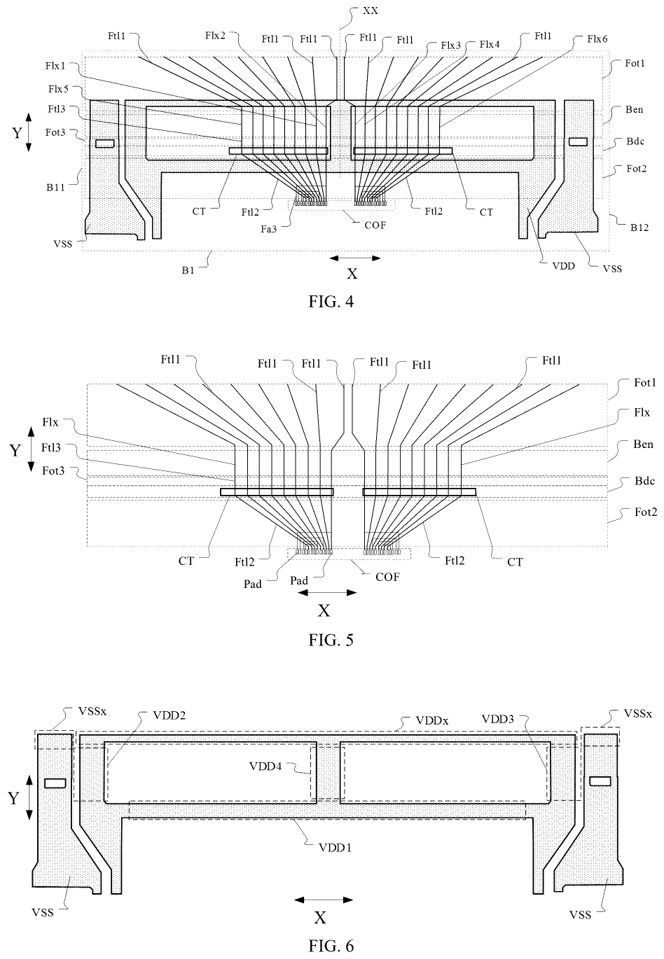

In view of this, an example embodiment provides another display panel, as shown in FIG. 4, which is a schematic structural diagram of a first border area in another example embodiment of a display panel in the present disclosure. In this example embodiment, the first border area may include a first fan-out area Fot1, a bending area Ben, an integrated area Bdc, and a second fan-out area Fot2. The bending area Ben is coupled to a side of the first fan-out area Fot1 away from the display area, the integrated area Bdc is coupled to a side of the bending area Ben away from the first fan-out area Fot1, and the second fan-out area Fot2 is coupled to a side of the integrated area Bdc away from the bending area Ben. FIG. 5 is a schematic structural diagram of individual signal lines in FIG. 4. As shown in FIG. 5, the display panel may further include a plurality of first fan-out lines Ftl1, a plurality of lead-out lines Flx, a detection unit CT, and a first power access line VDD. Orthographic projections of the plurality of first fan-out lines Ftl1 on the base substrate are located in the first fan-out area Fot1, the first fan-out lines Ftl1 are arranged corresponding to the data lines Da, the first fan-out lines Ftl1 are coupled to the corresponding data lines Da, and the first fan-out lines Ftl1 can be coupled to the first data lines Dal through the second data connection lines Fa2, or directly coupled to the second data lines Da2. Orthographic projections of the plurality of lead-out lines Flx on the base substrate are located in the bending area Ben, the lead-out lines Flx are arranged corresponding to the first fan-out lines Ftl1, and the lead-out lines Flx are coupled to the corresponding first fan-out lines Ftl1. An orthographic projection of the detection unit CT on the base substrate is located in the integrated area Bdc, and the detection unit CT is coupled to the lead-out line Flx. As shown in FIG. 6, which is a schematic structural diagram of a first power access line and a second power access line in FIG. 4, the first power access line VDD can be configured to provide a first power signal to the sub-pixel in the display panel, for example, the first power access line VDD can be configured to provide the first power terminal in FIG. 2. The first power access line VDD may include a first extension portion VDD1, a second extension portion VDD2, and a third extension portion VDD3. The first extension portion VDD1 is coupled between the second extension portion VDD2 and the third extension portion VDD3. An orthographic projection of the first extension portion VDD1 on the base substrate extends along the first direction X and is located in the second fan-out area Fot2. An orthographic projection of the second extension portion VDD2 on the base substrate extends along the second direction Y and is at least partially located in the bending area Ben. An orthographic projection of the third extension portion VDD3 on the base substrate extends along the second direction Y and is at least partially located in the bending area Ben. In the first direction X, the orthographic projection of the lead-out line Flx on the base substrate is located between the orthographic projection of the second extension portion VDD2 on the base substrate and the orthographic projection of the third extension portion VDD3 on the base substrate.

In an example embodiment, the orthographic projections of all lead-out lines Flx on the base substrate are located between the orthographic projections of the second extension portion VDD2 on the base substrate and the orthographic projections of the third extension portion VDD3 on the base substrate. The first fan-out line Ftl1 coupled to the lead-out line Flx does not need to avoid the second extension portion VDD2 and the third extension portion VDD3. Therefore, the first fan-out lines Ftl1 distributed in the first direction X will not have a problem of sudden length change.

As shown in FIGS. 4, 5 and 6, the first power access line VDD may further include a fourth extension portion VDD4 coupled to the first extension portion VDD1, an orthographic projection of the fourth extension portion VDD4 on the base substrate extends along the second direction Y and is at least partially located in the bending area Ben. In the first direction X, the orthographic projection of the fourth extension portion VDD4 on the base substrate is located between the orthographic projection of the second extension portion VDD2 on the base substrate and the orthographic projection of the third extension portion VDD3 on the base substrate. In the first direction X, orthographic projections of part of the lead-out lines Flx on the base substrate are located between the orthographic projection of the second extension portion VDD2 on the base substrate and the orthographic projection of the fourth extension portion VDD4 on the base substrate, and orthographic projections of part of the lead-out lines Flx on the base substrate are located between the orthographic projection of the third extension portion VDD3 on the base substrate and the orthographic projection of the fourth extension portion VDD4 on the base substrate. The plurality of lead-out lines Flx include a first lead-out line Flx1, a second lead-out line Flx2, a third lead-out line Flx3, and a fourth lead-out line Flx4 that are adjacent to each other in sequence in the first direction X. An orthographic projection of the second lead-out line Flx2 on the base substrate and an orthographic projection of the third lead-out line Flx3 on the base substrate are located on two adjacent sides of the orthographic projection of the fourth extension portion VDD4 on the base substrate. An orthographic projection of the first lead-out line Flx1 on the base substrate is located on a side where the orthographic projection of the second lead-out line Flx2 on the base substrate is away from the orthographic projection of the fourth extension portion VDD4 on the base substrate. An orthographic projection of the fourth lead-out line Flx4 on the base substrate is located on a side where the orthographic projection of the third lead-out line Flx3 on the base substrate is away from the orthographic projection of the fourth extension portion VDD4 on the base substrate. A length of an orthographic projection of a first fan-out line Ftl1 coupled to the second lead-out line Flx2 on the base substrate is greater than a length of an orthographic projection of a first fan-out line Ftl1 coupled to the first lead-out line Flx1 on the base substrate. A length of an orthographic projection of a first fan-out line Ftl1 coupled to the third lead-out line Flx3 on the base substrate is greater than a length of an orthographic projection of a first fan-out line Ftl1 coupled to the fourth lead-out line Flx4 on the base substrate. The orthographic projection of the first fan-out line Ftl1 coupled to the second lead-out line Flx2 on the base substrate and the orthographic projection of the first fan-out line Ftl1 coupled to the third lead-out line Flx3 on the base substrate can be symmetrical along the dividing line XX. This arrangement can also ensure that the first fan-out lines Ftl1 will not have a sudden change in length at both sides of the fourth extension portion VDD4.

As shown in FIGS. 4, 5 and 6, the first border area B1 may include a first side edge B11 and a second side edge B12 that are arranged opposite to each other in the first direction X, and the plurality of lead-out lines Flx include a fifth lead-out line Flx5 and a sixth lead-out line Flx6. Among the lead-out lines Flx, an orthographic projection of the fifth lead-out line Flx5 on the base substrate is closest to the first side edge B11, and an orthographic projection of the sixth lead-out line Flx6 on the base substrate is closest to the second side edge B12. A distance in the first direction X between the orthographic projection of the fourth extension portion VDD4 on the base substrate and the orthographic projection of the fifth lead-out line Flx on the base substrate may be equal to a distance in the first direction X between the orthographic projection of the fourth extension portion VDD4 on the base substrate and the orthographic projection of the sixth lead-out line Flx6 on the base substrate. Orthographic projections of the lead-out lines Flx on the base substrate may be distributed at equal intervals along the first direction X. That is, the dividing line XX may be located at a midline position of an area where the lead-out lines Flx are located in the first direction X.

It should be understood that in other example embodiments, the orthographic projection of the first fan-out line Ftl1 coupled to the second lead-out line Flx2 on the base substrate and the orthographic projection of the first fan-out line Ftl1 coupled to the third lead-out line Flx3 on the base substrate may also be arranged asymmetrically. As long as the orthographic projection of the first fan-out line Ftl1 coupled to the second lead-out line Flx2 on the base substrate and the orthographic projection of the first fan-out line Ftl1 coupled to the third lead-out line Flx3 on the base substrate are the same or close in length, the problem of sudden change in the length of the first fan-out line Ftl1 can be solved. In an example embodiment, a length of the orthographic projection of the first fan-out line Ftl1 coupled to the second lead-out line Flx on the base substrate is L1, a length of the orthographic projection of the first fan-out line Ftl1 coupled to the third lead-out line Flx on the base substrate is L2, (L1−L2)/L2 is greater than or equal to 0 and less than or equal to 5%. For example, (L1−L2)/L2 can be equal to 0, 0.5%, 1%, 2%, 3%, 4%, 5%, etc. In addition, it should be noted that in other example embodiments, the fourth extension portion VDD4 may not be provided in the present disclosure.

As shown in FIGS. 4, 5 and 6, in an example embodiment, the base substrate further includes a third fan-out area Fot3 and a binding area COF, the third fan-out area Fot3 is coupled between the bending area Ben and the integrated area Bdc, and the binding area COF is coupled to a side of the second fan-out area Fot2 away from the display area. The display panel further includes: a plurality of third fan-out lines Ftl3, a plurality of second fan-out lines Ftl2, a driving circuit (not shown in the figure), and a binding pin Pad. Orthographic projections of the third fan-out lines Ftl3 on the base substrate are located in the third fan-out area Fot3, and the third fan-out lines Ftl3 are coupled between the lead-out lines Flx and the detection unit CT. Orthographic projections of the second fan-out lines Ftl2 on the base substrate are located in the second fan-out area Fot2, and the second fan-out lines Ftl2 are coupled to the third fan-out lines Ftl3. The driving circuit is at least configured to provide the data signal to the data line. An orthographic projection of the binding pin Pad on the base substrate is located in the binding area COF, and the binding pin Pad is coupled between the second fan-out line Ftl2 and the driving circuit.

As shown in FIGS. 4, 5, and 6, in the present disclosure, an order of the data lines may be changed in the second fan-out area Fot2, so that the arrangement order of the binding pins Pad is the same as the arrangement order of the data lines in the display area, and accordingly, the display panel can match the conventional driving circuit. In addition, in the present disclosure, the integrated area Bdc where the detection unit CT is located is arranged between the bending area Ben and the second fan-out area Fot2, so that the orthographic projection of the third fan-out line Ftl3 on the base substrate can extend in a straight line along the second direction Y. This arrangement can greatly compress the size of the third fan-out area Fot3 in the second direction Y, thereby leaving enough space for the second fan-out area Fot2 to change the order. It should be understood that in other example embodiments, a small portion of the third fan-out lines Ftl3 located in both sides of the first direction X can also extend obliquely to the middle position.

As shown in FIGS. 4, 5 and 6, in an example embodiment, a size of the second fan-out area Fot2 in the second direction Y may be greater than the size of the third fan-out area Fot3 in the second direction Y. For example, the size of the second fan-out area Fot2 in the second direction Y is L3, the size of the third fan-out area Fot3 in the second direction Y is L4, and L3/L4 may be greater than or equal to 5 and less than or equal to 9, for example, L3/L4 may be equal to 5, 6, 7, 8, 9, etc.

As shown in FIGS. 4, 5 and 6, among first fan-out lines Ftl1 close to the first side edge B11, an orthographic projection of at least part of the structure of a first fan-out line Ftl1 on the base substrate is located on a side of an orthographic projections of a lead-out line Flx coupled thereto on the base substrate close to the first side edge B11. The first fan-out line Ftl1 close to the first side edge B11 refers to a first fan-out line Ftl1 whose orthographic projection on the base substrate is closer to the first side edge B11 than the second side edge B12. In an example embodiment, among the first fan-out lines Ftl1 close to the first side edge B11, the orthographic projection of the first fan-out line Ftl1 on the base substrate may extend obliquely toward a side away from the first side edge B11. It should be understood that in other example embodiments, the orthographic projection of the first fan-out line Ftl1 on the base substrate may also first extend toward the side away from the first side edge B11 along the first direction X, and then extend toward the bending area Ben along the second direction Y. Among first fan-out lines Ftl1 close to the second side edge, an orthographic projection of at least part of the structure of a first fan-out line Ftl1 on the base substrate is located on a side of an orthographic projection of a lead-out line Flx coupled thereto on the base substrate close to the second side edge B12. Similarly, the first fan-out line Ftl1 close to the second side edge B12 refers to a first fan-out line Ftl1 whose orthographic projection on the base substrate is farther from the first side edge B11 than from the second side edge B12. In an example embodiment, among the first fan-out lines Ftl1 close to the second side edge B12, the orthographic projection of the first fan-out line Ftl1 on the base substrate may extend obliquely toward a side away from the second side edge B12. It should be understood that in other example embodiments, the orthographic projection of the first fan-out line Ftl1 on the base substrate may also first extend toward the side away from the second side edge B12 along the first direction X, and then extend toward the bending area Ben along the second direction Y.

In an example embodiment, the display panel further includes: a power line (not shown). An orthographic projection of the power line on the base substrate is located in the display area and extends along the second direction Y, and the power line is configured to provide the first power signal to the sub-pixel, for example, the power line can be configured to provide the first power terminal in FIG. 2. As shown in FIGS. 4, 5, and 6, the display panel in the present disclosure may further include a first power connection line VDDx. An orthographic projection of the first power connection line VDDx on the base substrate can be located in the first fan-out area Fot1, and extends along the first direction X, and the first power connection line VDDx is coupled to a plurality of power lines. The first power access line VDD can be coupled to the first power connection line VDDx through the second extension portion VDD2, the third extension portion VDD3, and the fourth extension portion VDD4.

As shown in FIGS. 4, 5 and 6, the display panel may further include a second power access line VSS and a second power connection line VSSx. An orthographic projection of the second power connection line VSSx on the base substrate is located in the first fan-out area Fot1, and an orthographic projection of the second power access line VSS on the base substrate is at least partially located in the bending area Ben and the second fan-out area Fot2. The second power connection line VSSx may be coupled to a cathode ring in the display panel, or the second power connection line VSSx may form a partial structure of the cathode ring, and the second power access line VSS may be configured to provide a second power signal to the second power connection line VSSx. The second power signal may be a low-level power signal, for example, the second power access line VSS may provide the second power terminal in FIG. 2.

In an example embodiment, in the display panel, a partial structure, away from the display area, of the bending area Ben in the first border area can be bent to a non-display surface of the display panel through the bending area Ben.

In an example embodiment, the display panel may include a base substrate, a first active layer, a first insulation layer, a first gate layer, a buffer layer, a second active layer, a second insulation layer, a second gate layer, a dielectric layer, a third gate layer, a passivation layer, a first flat layer, a first source-drain layer, a second flat layer, a second source-drain layer, a third flat layer, and a third source-drain layer, which are sequentially stacked. Part of the structure of the first active layer can be used to form a channel region of a P-type transistor in the pixel driving circuit. Part of the structure of the first gate layer can be used to form the gate of the P-type transistor and the first electrode of the capacitor in the pixel driving circuit. Part of the structure of the second gate layer can be used to form a bottom gate of the N-type transistor and the second electrode of the capacitor in the pixel driving circuit. Part of the structure of the third gate layer can be used to form a top gate of the N-type transistor in the pixel driving circuit. Part of the structure of the first source-drain layer can be used to form a bridge portion coupling a transistor and a signal terminal. Part of the structure of the second source-drain layer can be used to form part of a power line, and part of the structure of the third source-drain layer can be used to form a data line and part of the power line. The first insulation layer and the second insulation layer may be a single-layer structure or a multi-layer structure. The materials of the first insulation layer and the second insulation layer may be at least one of silicon nitride, silicon oxide, and silicon oxynitride. The buffer layer may include at least one of a silicon oxide layer and a silicon nitride layer. The dielectric layer may be a silicon nitride layer. The passivation layer may be a silicon oxide layer. The materials of the first flat layer, the second flat layer, and the third flat layer may be organic materials, such as polyimide (PI), polyethylene terephthalate (PET), polyethylene naphthalate (PEN), silicon-glass bonding structure (SOG), etc. The base substrate may be a flexible base substrate or a rigid base substrate. The base substrate may be made of polyimide (PI), polyethylene terephthalate (PET), etc. The materials of the first gate layer and the second gate layer may be one of molybdenum, aluminum, copper, titanium, niobium, or an alloy, or a molybdenum/titanium alloy or laminate, etc. The materials of the first source-drain layer, the second source-drain layer, and the third source-drain layer may include metal materials, for example, one of molybdenum, aluminum, copper, titanium, niobium, or an alloy, or a molybdenum/titanium alloy or laminate, or a titanium/aluminum/titanium laminate. The square resistance of the first source-drain layer, the second source-drain layer, and the third source-drain layer may be smaller than the square resistance of the first gate layer, the second gate layer, and the third gate layer. The first active layer may be formed of polysilicon material, and the second active layer may be formed of indium gallium zinc oxide.

It should be understood that in other example embodiments, the pixel driving circuit in the display panel may have other structures, for example, the pixel driving circuit may not include the eighth transistor, and for another example, the first transistor and the second transistor may be P-type transistors. Accordingly, the display panel may also have other architectures, for example, when the pixel driving circuit includes only one type of transistor, the display panel may not include the third gate layer and the second active layer. In addition, the display panel may also only have the first source-drain layer and the second source-drain layer, and the data line may be located at the second source-drain layer.

FIG. 7 is a partial enlarged view of a first fan-out area in FIG. 4. As shown in FIG. 7, the plurality of first fan-out lines Ftl1 may include a plurality of first sub-fan-out lines Ftl1x and a plurality of second sub-fan-out lines Ftlly. The first sub-fan-out lines Ftl1x may be located in the first gate layer of the display panel, and the second sub-fan-out lines Ftlly may be located in the second gate layer of the display panel. Orthographic projections of the plurality of first sub-fan-out lines Ftl1x and the plurality of second sub-fan-out lines Ftlly on the base substrate may be alternately distributed in sequence along the first direction X. This arrangement may improve the integration of the first fan-out lines Ftl1.

Similarly, part of the second fan-out lines Ftl2 is located in the first gate layer, part of the second fan-out line Ftl2 is located in the second gate layer, and orthographic projections of the second fan-out lines Ftl2 located in the first gate layer on the base substrate and orthographic projections of the second fan-out lines Ftl2 located in the second gate layer on the base substrate are alternately distributed in sequence in the first direction X. Part of the third fan-out lines Ftl3 is located in the first gate layer, part of the third fan-out lines Ftl3 is located in the second gate layer, and orthographic projections of the third fan-out lines Ftl3 located in the first gate layer on the base substrate and orthographic projections of the third fan-out lines Ftl3 located in the second gate layer on the base substrate are alternately distributed in sequence in the first direction X. Part of the binding pins Pad is located in the first gate layer, part of the binding pins Pad is located in the second gate layer, and orthographic projections of the binding pins Pad located in the first gate layer on the base substrate and orthographic projections of the binding pins Pad located in the second gate layer on the base substrate are alternately distributed in sequence in the first direction X.

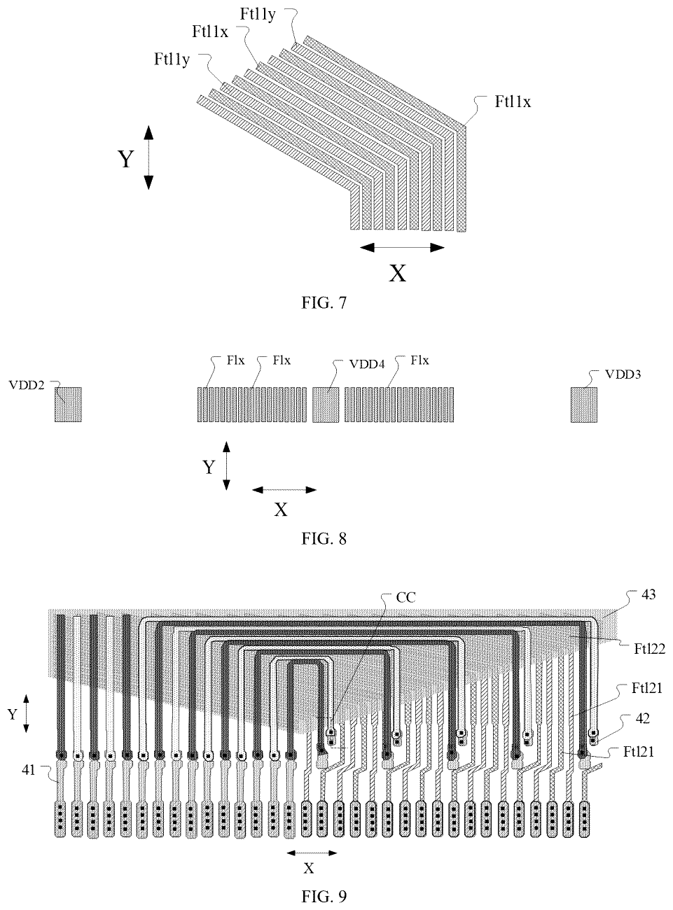

FIG. 8 is a schematic structural diagram of a bending area in FIG. 4. As shown in FIG. 8, an orthogonal projection on the base substrate of part of the second extension portion VDD2 whose orthographic projection on the base substrate is located in the bending area Ben, an orthogonal projection on the base substrate of part of the third extension portion VDD3 whose orthographic projection on the base substrate is located in the bending area Ben, and an orthogonal projection on the base substrate of part of the fourth extension portion VDD4 whose orthographic projection on the base substrate is located in the bending area Ben do not overlap with an orthographic projection of the lead-out line Flx on the base substrate. On the one hand, this arrangement can make the part of the second extension portion VDD2 whose orthographic projection on the base substrate is located in the bending area Ben, the part of the third extension portion VDD3 whose orthographic projection on the base substrate is located in the bending area Ben, and the part of the fourth extension portion VDD4 whose orthographic projection on the base substrate is located in the bending area Ben be located in the same conductive layer as the lead-out line Flx. For example, the part of the second extension portion VDD2 whose orthographic projection on the base substrate is located in the bending area Ben, the part of the third extension portion VDD3 whose orthographic projection on the base substrate is located in the bending area Ben, the part of the fourth extension portion VDD4 whose orthographic projection on the base substrate is located in the bending area Ben and the lead-out line Flx can be located in the first source-drain layer. On the other hand, this arrangement can reduce the parasitic capacitance between the data line and the power line. It should be understood that in other example embodiments, the part of the second extension portion VDD2 whose orthographic projection on the base substrate is located in the bending area Ben, the part of the third extension portion VDD3 whose orthographic projection on the base substrate is located in the bending area Ben, and the part of the fourth extension portion VDD4 whose orthographic projection on the base substrate is located in the bending area Ben can also be located in different conductive layers from the lead-out line Flx.

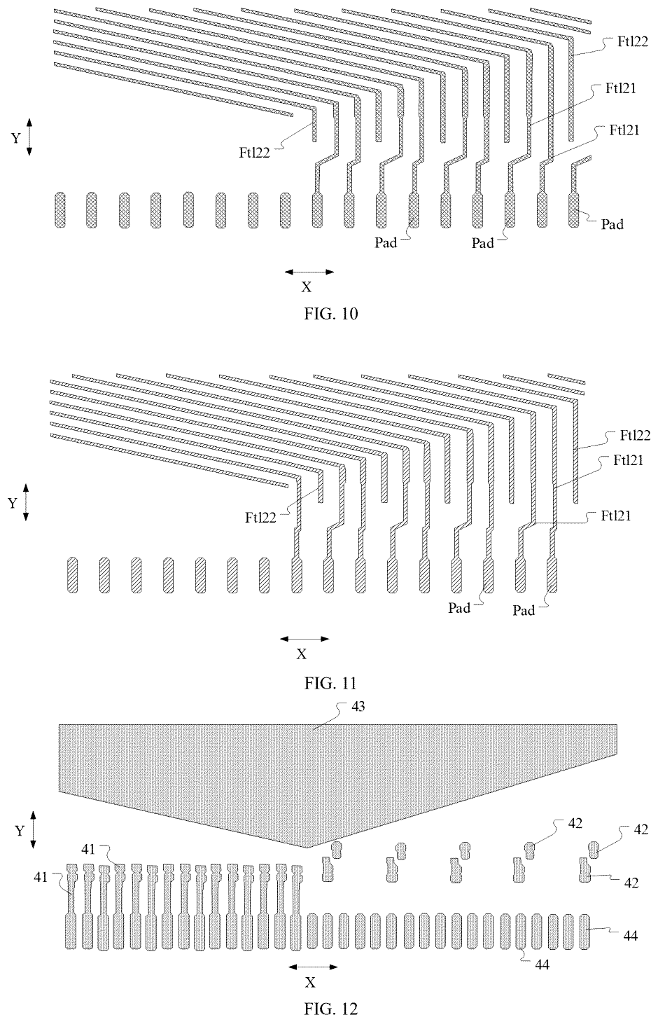

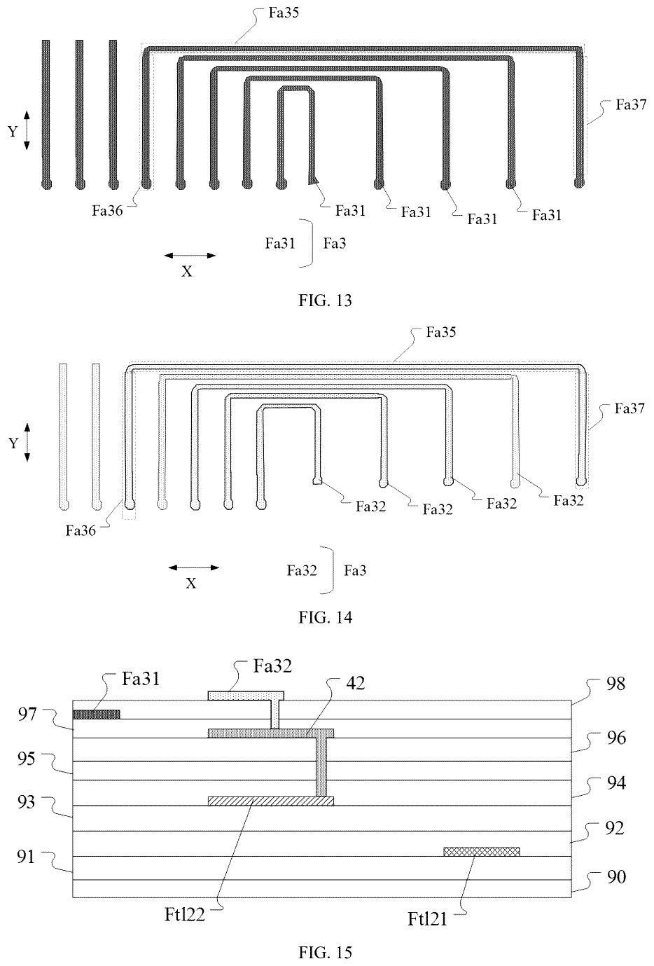

As shown in FIGS. 9-14, FIG. 9 is a partial enlarged view of a second fan-out area and a binding area in FIG. 4, FIG. 10 is a structural layout diagram of a first gate layer in FIG. 9, FIG. 11 is a structural layout diagram of a second gate layer in FIG. 9, FIG. 12 is a structural layout diagram of a first source-drain layer in FIG. 9, FIG. 13 is a structural layout diagram of a second source-drain layer in FIG. 9, and FIG. 14 is a structural layout diagram of a third source-drain layer in FIG. 9.

As shown in FIGS. 9-14, the plurality of second fan-out lines Ftl2 may include: a plurality of first sub-fan-out lines Ftl21 and a plurality of second sub-fan-out lines Ftl22. The first sub-fan-out line Ftl21 is arranged corresponding to the second data line Da2 in FIG. 1, and the first sub-fan-out line Ftl21 is coupled between the corresponding second data line Da2 and the binding pin Pad. The second sub-fan-out line Ftl22 is arranged corresponding to the second data connection line Fa2 in FIG. 1, and the second sub-fan-out line Ftl22 is coupled to the corresponding second data connection line Fa2. The display panel may further include a third data connection line Fa3, and an orthographic projection of the third data connection line Fa3 on the base substrate is located in the second fan-out area Fot2. Part of the third data connection lines Fa3 may be located in the second source-drain layer of the display panel, and part of the third data connection lines Fa3 may be located in the third source-drain layer of the display panel. The third data connection line Fa3 may include a fifth extension portion Fa35 and a sixth extension portion Fa36, an orthographic projection of the fifth extension portion Fa35 on the base substrate extends along the first direction X, and an orthographic projection of the sixth extension portion Fa36 on the base substrate extends along the second direction Y. The fifth extension portion Fa35 is connected to the second sub-fan-out line Ftl22, and the sixth extension portion Fa36 may be coupled between the binding pin Pad and the fifth extension portion Fa35. The orthographic projection of the fifth extension portion Fa35 on the base substrate intersects with orthographic projections of at least part of the first sub-fan-out lines Ftl21 on the base substrate. In this example embodiment, the second fan-out lines Ftl2 are reordered through the third data connection line Fa3, so that the arrangement order of the binding pins Pad in the first direction X is the same as the arrangement order of the data lines coupled thereto in the first direction X. The sixth extension portion Fa36 can be coupled to the binding pin Pad through a first bridge portion 41. The sixth extension portion Fa36 is coupled to the first bridge portion 41 through a via hole, and the first bridge portion 41 is coupled to the binding pin Pad through a via hole. A black square in FIG. 9 indicates a position of the via hole. The first bridge portion 41 can be located in the first source-drain layer of the display panel.

As shown in FIG. 4, in an example embodiment, the orthographic projection of the third data connection line Fa3 on the base substrate is located on a side of the orthographic projection of the first extension portion VDD1 on the base substrate away from the orthographic projection of the detection unit CT on the base substrate.

As shown in FIGS. 9-14, the third data connection line Fa3 further includes a seventh extension portion Fa37, the seventh extension portion Fa37 is coupled between the fifth extension portion Fa35 and the second sub-fan-out line Ftl22, and an orthographic projection of the seventh extension portion Fa37 on the base substrate extends along the second direction Y. The seventh extension portion Fa37 can be coupled to the second sub-fan-out line Ftl22 through a second bridge portion 42, where the seventh extension portion Fa37 can be coupled to the second bridge portion 42 through a via hole, and the second bridge portion 42 is coupled to the second sub-fan-out line Ftl22 through a via hole. The second bridge portion 42 can be located in the first source-drain layer of the display panel. It should be noted that in other example embodiments, the fifth extension portion Fa35 and the second sub-fan-out line Ftl22 can also be directly coupled. That is, the third data connection line Fa3 may not include the seventh extension portion Fa37.

As shown in FIGS. 9-14, the plurality of third data connection lines Fa3 may include a plurality of first sub-data connection lines Fa31 and a plurality of second sub-data connection lines Fa32, the first sub-data connection lines Fa31 may be located in the second source-drain layer, and the second sub-data connection lines Fa32 may be located in the third source-drain layer. Orthographic projections of the first sub-data connection lines Fa31 on the base substrate and orthographic projections of the second sub-data connection lines Fa32 on the base substrate are alternately distributed in the second direction Y in sequence. This arrangement may improve the integration of the third data connection lines Fa3. It should be understood that in other example embodiments, the third data connection lines Fa3 may be located in the same conductive layer, and the first sub-data connection lines Fa31 and the plurality of second sub-data connection lines Fa32 may also be located in other conductive layers, respectively. For example, the first sub-data connection lines Fa31 and the second sub-data connection lines Fa32 may also be located in the first source-drain layer and the second source-drain layer, respectively.

As shown in FIGS. 9-14, the display panel may further include a shielding portion 43, and the shielding portion 43 may be coupled to a stable voltage source, for example, the shielding portion 43 may be coupled to the first extension portion VDD1. The shielding portion 43 may be located between a conductive layer where the second fan-out line Ftl2 is located and a conductive layer where the third data connection line Fa3 is located, for example, the shielding portion 43 may be located in the first source-drain layer. The shielding portion 43 may shield between the second fan-out line Ftl2 and the third data connection line Fa3, thereby reducing interference between different data signals.

As shown in FIGS. 9-14, the first sub-data connection line Fa31 located in the second source-drain layer can be coupled to the second fan-out line Ftl2 located in the first gate layer, and the second sub-data connection line Fa32 located in the third source-drain layer can be coupled to the second fan-out line Ftl2 located in the second gate layer. This arrangement can make lengths of connection via holes between different third data connection lines Fa3 and second fan-out lines Ftl2 similar, thereby reducing the resistance difference between different data leads. The data leads include a data line, and a fan-out line and a lead coupled to the data line.

As shown in FIGS. 9-14, the display panel may further include a plurality of analog bridge portions 44. The analog bridge portion 44 may be coupled to, through the via hole, the binding pin Pad coupled to the first sub-fan-out line Ftl21. The dummy bridge portions 44 may mimics the conductive effect of the first bridge portion 41 to reduce the resistance difference between different data leads. In addition, the analog bridge portion 44 may also simulate the parasitic capacitance, shading and other characteristics of the first bridge portion 41 to improve the uniformity of structures at different positions of the display panel, thereby improving the uniformity of the display of the display panel.

FIG. 15 is a cross-sectional view taken along a dotted line CC in FIG. 9. As shown in FIG. 15, the base substrate 90, the first insulation layer 91, the first gate layer, the buffer layer 92, the second insulation layer 93, the second gate layer, the dielectric layer 94, the passivation layer 95, the first flat layer 96, the first source-drain layer, the second flat layer 97, the second source-drain layer, the third flat layer 98, and the third source-drain layer are stacked in sequence.

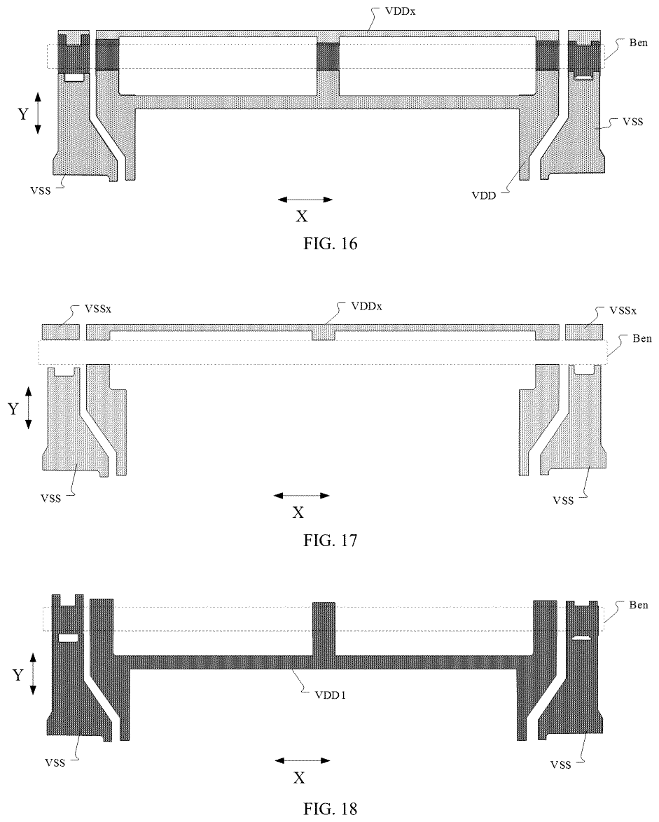

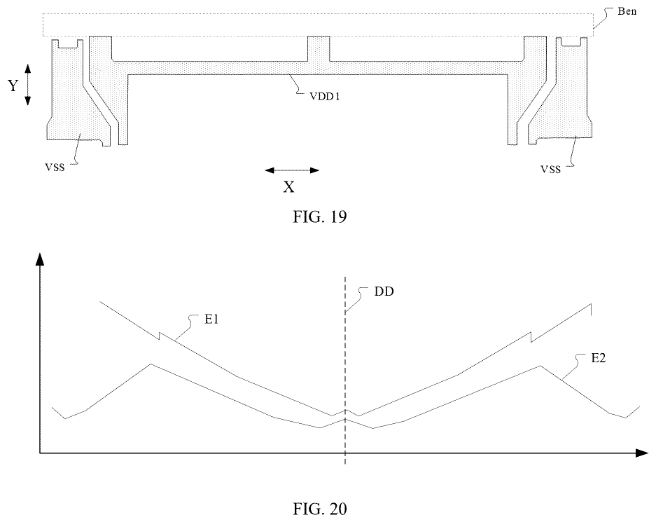

As shown in FIGS. 16-19, FIG. 16 is a structural layout diagram of a first power access line and a second power access line in FIG. 6, FIG. 17 is a structural layout diagram of a first source-drain layer in FIG. 16, FIG. 18 is a structural layout diagram of a second source-drain layer in FIG. 16, and FIG. 19 is a structural layout diagram of a third source-drain layer in FIG. 16.

The first extension portion VDD1 is located in the second source-drain layer and the third source-drain layer. Parts of the first power access line VDD and the second power access line VSS which are located in the bending area Ben are only arranged in the second source-drain layer. The first power connection line VDDx and the second power connection line VSSx can be arranged in the first source-drain layer. It should be understood that in other example embodiments, the first power connection line VDDx and the second power connection line VSSx can also be located in any one or more layers of the first source-drain layer, the second source-drain layer, and the third source-drain layer.

FIG. 20 is a diagram showing a resistance variation of data lead-out lines at different positions of a display panel in the present disclosure. As shown in FIG. 20, the horizontal axis represents different positions of the display panel in the first direction X, and the dotted line DD in FIG. 20 represents a midline position of the display panel in the first direction. The vertical axis represents the resistance of the data lead. El represents the resistance change diagram of the data lead-out line at different positions of the display panel in the embodiment shown in FIGS. 3, and E2 represents the resistance change diagram of the data lead-out line at different positions of the display panel in the embodiment shown in FIG. 4. According to FIG. 20, it can be seen that in the embodiment shown in FIG. 3, there is a sudden change in resistance of the data line, and the embodiment shown in FIG. 4 can improve the sudden change problem.

Embodiments of the present disclosure further provide a display device, which includes the above-mentioned display panel. The display device can be a display device such as a mobile phone, a tablet computer, a television, etc.

Other embodiments of the present disclosure will be apparent to those skilled in the art from consideration of the specification and practice of the present disclosure disclosed herein. The present disclosure is intended to cover any variations, uses, or adaptations of the present disclosure, which are in accordance with the general principles of the present disclosure and include common general knowledge or conventional technical means in the art that are not disclosed in the present disclosure. The specification and embodiments are illustrative, and the real scope and spirit of the present disclosure is defined by the appended claims.

It should be understood that the present disclosure is not limited to the precise structures that have been described above and shown in the drawings, and various modifications and changes can be made without departing from the scope thereof. The scope of the present disclosure is limited only by the appended claims.

1. A display panel, comprising:
a base substrate, comprising a display area and a first border area coupled to a side of the display area in a second direction, wherein the first border area comprises a first fan-out area, a bending area, an integrated area and a second fan-out area, the bending area is coupled to a side of the first fan-out area away from the display area, the integrated area is coupled to a side of the bending area away from the first fan-out area, and the second fan-out area is coupled to a side of the integrated area away from the bending area;
a plurality of sub-pixels, wherein orthographic projections of the plurality of sub-pixels on the base substrate are located in the display area;
a plurality of data lines, wherein orthographic projections of the plurality of data lines on the base substrate are located in the display area, and the data lines are configured to provide data signals to the sub-pixels;
a plurality of first fan-out lines, wherein orthographic projections of the plurality of first fan-out lines on the base substrate are located in the first fan-out area, the first fan-out lines are arranged corresponding to the data lines, and the first fan-out lines are coupled to corresponding data lines;
a plurality of lead-out lines, wherein orthographic projections of the plurality of lead-out lines on the base substrate are located in the bending area, the lead-out lines are arranged corresponding to the first fan-out lines, and the lead-out lines are coupled to corresponding first fan-out lines;
a detection unit, wherein an orthographic projection of the detection unit on the base substrate is located in the integrated area, and the detection unit is coupled to the lead-out lines; and
a first power access line, configured to provide a first power signal to the sub-pixels, wherein the first power access line comprises a first extension portion, a second extension portion and a third extension portion, and the first extension portion is coupled between the second extension portion and the third extension portion;
wherein an orthographic projection of the first extension portion on the base substrate is extended along a first direction and is located in the second fan-out area, an orthographic projection of the second extension portion on the base substrate is extended along the second direction and is at least partially located in the bending area, an orthographic projection of the third extension portion on the base substrate is extended along the second direction and is at least partially located in the bending area, and the first direction is intersected with the second direction; and
in the first direction, the orthographic projections of the lead-out lines on the base substrate are located between the orthographic projection of the second extension portion on the base substrate and the orthographic projection of the third extension portion on the base substrate.

2. The display panel according to claim 1, wherein the first power access line further comprises a fourth extension portion coupled to the first extension portion, and an orthographic projection of the fourth extension portion on the base substrate is extended along the second direction and is at least partially located in the bending area;
in the first direction, the orthographic projection of the fourth extension portion on the base substrate is located between the orthographic projection of the second extension portion on the base substrate and the orthographic projection of the third extension portion on the base substrate; and
in the first direction, orthographic projections of part of the lead-out lines on the base substrate are located between the orthographic projection of the second extension portion on the base substrate and the orthographic projection of the fourth extension portion on the base substrate, and orthographic projections of the other part of the lead-out lines on the base substrate are located between the orthographic projection of the third extension portion on the base substrate and the orthographic projection of the fourth extension portion on the base substrate.

3. The display panel according to claim 2, wherein the plurality of lead-out lines comprise a first lead-out line, a second lead-out line, a third lead-out line and a fourth lead-out line that are adjacent to each other in sequence in the first direction;
an orthographic projection of the second lead-out line on the base substrate and an orthographic projection of the third lead-out line on the base substrate are located on two adjacent sides of the orthographic projection of the fourth extension portion on the base substrate;
an orthographic projection of the first lead-out line on the base substrate is located on a side where the orthographic projection of the second lead-out line on the base substrate is away from the orthographic projection of the fourth extension portion on the base substrate, and an orthographic projection of the fourth lead-out line on the base substrate is located on a side where the orthographic projection of the third lead-out line on the base substrate is away from the orthographic projection of the fourth extension portion on the base substrate; and
a length of an orthographic projection of a first fan-out line coupled to the second lead-out line on the base substrate is greater than a length of an orthographic projection of a first fan-out line coupled to the first lead-out line on the base substrate, and a length of an orthographic projection of a first fan-out line coupled to the third lead-out line on the base substrate is greater than a length of an orthographic projection of a first fan-out line coupled to the fourth lead-out line on the base substrate.

4. The display panel according to claim 3, wherein the orthographic projection of the first fan-out line coupled to the second lead-out line on the base substrate and the orthographic projection of the first fan-out line coupled to the third lead-out line on the base substrate are symmetrical along a dividing line.

5. (canceled)

6. The display panel according to claim 2, wherein the first border area comprises a first side edge and a second side edge arranged opposite to each other in the first direction, and the plurality of lead-out lines comprise a fifth lead-out line and a sixth lead-out line;
among the lead-out lines, an orthographic projection of the fifth lead-out line on the base substrate is closest to the first side edge, and an orthographic projection of the sixth lead-out line on the base substrate is closest to the second side edge; and
a distance in the first direction between the orthographic projection of the fourth extension portion on the base substrate and the orthographic projection of the fifth lead-out line on the base substrate is equal to a distance in the first direction between the orthographic projection of the fourth extension portion on the base substrate and the orthographic projection of the sixth lead-out line on the base substrate.

7. The display panel according to claim 1, wherein the base substrate further comprises a third fan-out area and a binding area, the third fan-out area is coupled between the bending area and the integrated area, and the binding area is coupled to a side of the second fan-out area away from the display area;
the display panel further comprises:
a third fan-out line, wherein an orthographic projection of the third fan-out line on the base substrate is located in the third fan-out area, and the third fan-out line is coupled between a lead-out line and the detection unit;
a second fan-out line, wherein an orthographic projection of the second fan-out line on the base substrate is located in the second fan-out area, and the second fan-out line is coupled to the third fan-out line;
a driving circuit, wherein the driving circuit is at least configured to provide a data signal to a data line; and
a binding pin, wherein an orthographic projection of the binding pin on the base substrate is located in the binding area, and the binding pin is coupled between the second fan-out line and the driving circuit.

8. The display panel according to claim 7, wherein orthographic projections of at least part of third fan-out lines on the base substrate are extended linearly along the second direction.

9. The display panel according to claim 7, wherein a size of the second fan-out area in the second direction is greater than a size of the third fan-out area in the second direction.

10. (canceled)

11. The display panel according to claim 7, wherein the orthographic projections of the plurality of data lines on the base substrate are distributed at intervals along the first direction and are extended along the second direction, and the plurality of data lines comprise a first data line and a second data line;
the display area further comprises a fourth fan-out area, and the display panel further comprises:
a plurality of first data connection lines, located in the fourth fan-out area, wherein orthographic projections of the first data connection lines on the base substrate are distributed at intervals along the second direction and are extended along the first direction, the first data connection lines are coupled between corresponding first data lines and first fan-out lines, and the orthographic projections of the first data connection lines on the base substrate are overlapped with orthographic projections of at least part of second data lines on the base substrate; and
a plurality of second data connection lines, located in the fourth fan-out area, wherein orthographic projections of the second data connection lines on the base substrate are distributed at intervals along the first direction and are extended along the second direction, and the second data connection lines are coupled between the first data connection lines and the first fan-out lines.

12. The display panel according to claim 11, wherein the display area comprises a third side edge and a fourth side edge arranged opposite to each other in the first direction; and
an orthographic projection of the first data line on the base substrate is located on a side where an orthographic projection of the second data line on the base substrate is close to the third side edge or the fourth side edge.

13. The display panel according to claim 1, wherein the first border area comprises a first side edge and a second side edge arranged opposite to each other in the first direction;
in a first fan-out line close to the first side edge, an orthographic projection of at least part of a structure of the first fan-out line on the base substrate is located on a side where an orthographic projection of a lead-out line coupled to the first fan-out line on the base substrate is close to the first side edge; and
in a first fan-out line close to the second side edge, an orthographic projection of at least part of a structure of the first fan-out line on the base substrate is located on a side where an orthographic projection of a lead-out line coupled to the first fan-out line on the base substrate is close to the second side edge.

14. The display panel according to claim 2, wherein a part of the second extension portion whose orthographic projection on the base substrate is located in the bending area and the lead-out lines are located in the same conductive layer;
a part of the third extension portion whose orthographic projection on the base substrate is located in the bending area and the lead-out lines are located in the same conductive layer; and
a part of the fourth extension portion whose orthographic projection on the base substrate is located in the bending area and the lead-out lines are located in the same conductive layer.

15. The display panel according to claim 2, wherein the display panel further comprises:
a power line, wherein an orthographic projection of the power line on the base substrate is located in the display area and is extended along the second direction, and the power line is configured to provide the first power signal to the sub-pixels; and
a first power connection line, wherein an orthographic projection of the first power connection line on the base substrate is located in the first fan-out area and is extended along the first direction, and the first power connection line is coupled to a plurality of power lines;
wherein the first power access line is coupled to the first power connection line through the second extension portion, the third extension portion and the fourth extension portion.

16. The display panel according to claim 11, wherein a plurality of second fan-out lines comprise:
a plurality of first sub-fan-out lines, wherein the first sub-fan-out lines are arranged corresponding to the second data lines, and the first sub-fan-out lines are coupled to corresponding second data lines; and
a plurality of second sub-fan-out lines, wherein the second sub-fan-out lines are arranged corresponding to the second data connection lines, and the second sub-fan-out lines are coupled to corresponding second data connection lines;
the display panel further comprises:
a third data connection line, wherein an orthographic projection of the third data connection line on the base substrate is located in the second fan-out area, the third data connection line comprises a fifth extension portion and a sixth extension portion, an orthographic projection of the fifth extension portion on the base substrate is extended along the first direction, an orthographic projection of the sixth extension portion on the base substrate is extended along the second direction, the fifth extension portion is coupled to the second sub-fan-out lines, and the sixth extension portion is coupled between the binding pin and the fifth extension portion;
wherein the orthographic projection of the fifth extension portion on the base substrate is intersected with orthographic projections of at least part of the first sub-fan-out lines on the base substrate; and
an arrangement order of binding pins in the first direction is the same as an arrangement order of data lines coupled thereto in the first direction.

17. The display panel according to claim 16, wherein the third data connection line further comprises a seventh extension portion coupled between the fifth extension portion and the second sub-fan-out lines, and an orthographic projection of the seventh extension portion on the base substrate is extended along the second direction.

18. The display panel according to claim 16, wherein a plurality of third data connection lines comprise a plurality of first sub-data connection lines and a plurality of second sub-data connection lines, and the first sub-data connection lines and the second sub-data connection lines are located in different conductive layers; and
orthographic projections of the first sub-data connection lines on the base substrate and orthographic projections of the second sub-data connection lines on the base substrate are alternately distributed in sequence in the second direction.

19. The display panel according to claim 18, wherein the display panel further comprises:
a first gate layer, located on a side of the base substrate;
a second gate layer, located on a side of the base substrate away from the first gate layer;
wherein part of the second fan-out lines is located in the first gate layer, part of the second fan-out lines is located in the second gate layer, and orthographic projections of second fan-out lines located in the first gate layer on the base substrate and orthographic projections of second fan-out lines located in the second gate layer on the base substrate are alternately distributed in sequence in the first direction;
a first source-drain layer, located on a side of the second gate layer away from the base substrate, wherein the first source-drain layer comprises a shielding portion coupled to a stable voltage source;
a second source-drain layer, located on a side of the first source-drain layer away from the base substrate, wherein the first sub-data connection lines are located in the second source-drain layer; and
a third source-drain layer, located on a side of the second source-drain layer away from the base substrate, wherein the second sub-data connection lines are located in the third source-drain layer;
wherein the shielding portion shields between the second fan-out lines and the third data connection lines.

20. The display panel according to claim 19, wherein orthographic projections of the third data connection lines on the base substrate are located on a side wherein the orthographic projection of the first extension portion on the base substrate is away from the orthographic projection of the detection unit on the base substrate; and
the shielding portion is coupled to the first extension portion.

21. The display panel according to claim 7, wherein the display panel further comprises:
a first gate layer, located on a side of the base substrate; and
a second gate layer, located on a side of the base substrate facing away from the first gate layer;
wherein part of the first fan-out lines is located in the first gate layer, part of the first fan-out lines is located in the second gate layer, and orthographic projections of first fan-out lines located in the first gate layer on the base substrate and orthographic projections of first fan-out lines located in the second gate layer on the base substrate are alternately distributed in sequence in the first direction; and
part of third fan-out lines is located in the first gate layer, part of the third fan-out lines is located in the second gate layer, and orthographic projections of third fan-out lines located in the first gate layer on the base substrate and orthographic projections of third fan-out lines located in the second gate layer on the base substrate are alternately distributed in sequence in the first direction.

22. (canceled)

23. A display device, comprising a display panel, wherein the display panel comprises:
a base substrate, comprising a display area and a first border area coupled to a side of the display area in a second direction, wherein the first border area comprises a first fan-out area, a bending area, an integrated area and a second fan-out area, the bending area is coupled to a side of the first fan-out area away from the display area, the integrated area is coupled to a side of the bending area away from the first fan-out area, and the second fan-out area is coupled to a side of the integrated area away from the bending area;
a plurality of sub-pixels, wherein orthographic projections of the plurality of sub-pixels on the base substrate are located in the display area;
a plurality of data lines, wherein orthographic projections of the plurality of data lines on the base substrate are located in the display area, and the data lines are configured to provide data signals to the sub-pixels;
a plurality of first fan-out lines, wherein orthographic projections of the plurality of first fan-out lines on the base substrate are located in the first fan-out area, the first fan-out lines are arranged corresponding to the data lines, and the first fan-out lines are coupled to corresponding data lines;
a plurality of lead-out lines, wherein orthographic projections of the plurality of lead-out lines on the base substrate are located in the bending area, the lead-out lines are arranged corresponding to the first fan-out lines, and the lead-out lines are coupled to corresponding first fan-out lines;
a detection unit, wherein an orthographic projection of the detection unit on the base substrate is located in the integrated area, and the detection unit is coupled to the lead-out lines; and
a first power access line, configured to provide a first power signal to the sub-pixels, wherein the first power access line comprises a first extension portion, a second extension portion and a third extension portion, and the first extension portion is coupled between the second extension portion and the third extension portion;
wherein an orthographic projection of the first extension portion on the base substrate is extended along a first direction and is located in the second fan-out area, an orthographic projection of the second extension portion on the base substrate is extended along the second direction and is at least partially located in the bending area, an orthographic projection of the third extension portion on the base substrate is extended along the second direction and is at least partially located in the bending area, and the first direction is intersected with the second direction; and
in the first direction, the orthographic projections of the lead-out lines on the base substrate are located between the orthographic projection of the second extension portion on the base substrate and the orthographic projection of the third extension portion on the base substrate.
